(19) United States
(12) Patent Application Publication
(10) Pub. No.: US 2026/0348679 A1
(43) Pub. Date: Nov. 5, 2026

(54) INCLINED PIN HEATSINK FOR IMPINGEMENT COOLING

(71) Applicant: THE JOHNS HOPKINS UNIVERSITY, Baltimore, MD (US)

(72) Inventors: Jessica Degner, Baltimore, MD (US); Harry Charles, Jr., Baltimore, MD (US); Rajat Mittal, Baltimore, MD (US); Jung-Hee Seo, Baltimore, MD (US)

(21) Appl. No.: 18/997,714

(22) PCT Filed: Jul. 24, 2023
(86) PCT No.: PCT/US2023/070868

§ 371 Date: Jan. 22, 2025

(51) Int. Cl. F28F 3/02; F28D 21/00; F28F 3/04

(52) U.S. Cl. CPC F28F 3/022; F28F 3/04; F28D 2021/0029; F28F 2215/00

(57) ABSTRACT

An inclined pin heatsink is designed to provide efficient cooling in a small footprint. The inclined pin heatsink provides cooling directly, for example, to hot components of an electronic device, and more specifically provides cooling to hot components on a printed electronic circuit board (PCB). The inclined pin heatsink of the present invention achieves cooling without the need to bring heat out of a system with much bulkier and sizeable solutions.

### CROSS REFERENCE TO RELATED APPLICATIONS

This application claims the benefit of U.S. Provisional Patent Application No. 63/391,443 filed on, Jul. 22, 2022, which is incorporated by reference, herein, in its entirety.

### FIELD OF THE INVENTION

The present invention relates generally to heatsinks. More particularly the present invention relates to inclined pin heatsinks for impingement cooling.

### BACKGROUND OF THE INVENTION

As electronics continue to move to smaller, more densely packed designs, heat dissipation will continue to be an issue. Traditionally, electronics are cooled in one of or a combination of the following ways, heatsinks (or mass) are added for improved conduction, internal or external fans are added for forced or convection cooling, or liquid cooling/phase change cooling could be utilized. However, each of these methods has a tradeoff. For small, compact, human-portable or UAV applications, additional weight or size may not be possible. Fans are a great way to improve the cooling, but when the end user is operating in non-ideal environments, they may not be the best solution, not only for the environmental concerns, but fans can also be loud, drawing attention to the end user. In addition, for human-portable electronics, fans can add an additional power burden on batteries, shortening mission duration. Typically liquid cooled solutions are reserved for high powered electronics on larger scales. There is additional complexity in the designs that include routing plumbing and safety concerns as well (burst pipes, leaking refrigerant, etc.).

It would therefore be advantageous to provide new, efficient designs for heatsinks.

### SUMMARY

According to a first aspect of the present invention a device for impingement cooling includes a base. The device further includes pins extending from the base. A number of the pins are arranged at a number of angles to the base.

In accordance with an aspect of the present invention, the angles to the base are greater than 90°. The angles to the base can also be less than 90°. The device can also include pins wherein the angles to the base include angles that are greater than 90°, less than 90°, and equal to 90°. Some of the number of the pins are angled toward a center of the device, and others of the number of pins are angled away from a center of the device.

In accordance with another aspect of the present invention, the device can be formed from a metal, an alloy, or a conductive material. The device can be formed by additive manufacturing or three-dimensional printing.

In accordance with another aspect of the present invention, a system for impingement cooling includes a microblower. The system also includes a heatsink. The heatsink includes a base. The heatsink further includes pins extending from the base. A number of the pins are arranged at a number of angles to the base.

In accordance with yet another aspect of the present invention, the microblower can take the form of a piezoelectrically controlled synthetic jet. the angles to the base are greater than 90°. The angles to the base can also be less than 90°. The device can also include pins wherein the angles to the base include angles that are greater than 90°, less than 90°, and equal to 90°. Some of the number of the pins are angled toward a center of the device, and others of the number of pins are angled away from a center of the device.

In accordance with another aspect of the present invention, the device can be formed from a metal, an alloy, or a conductive material. The device can be formed by additive manufacturing or three-dimensional printing.

In accordance with yet another aspect of the present invention, a system for impingement cooling includes a piezoelectrically controlled synthetic jet. The system also includes a heatsink. The heatsink takes the form of a base and a fluid flow path defining structure disposed on the heatsink base.

### BRIEF DESCRIPTION OF THE DRAWINGS

The accompanying drawings provide visual representations which will be used to more fully describe the representative embodiments disclosed herein and can be used by those skilled in the art to better understand them and their inherent advantages. In these drawings, like reference numerals identify corresponding elements and:

FIGS. 1 and 2 illustrate a perspective view and a side view, respectively, of an inclined pin heatsink, according to an embodiment of the present invention.

FIGS. 3 and 4 illustrate a side view and perspective view, respectively, of an inclined pin heatsink, according to an embodiment of the present invention.

FIGS. 5 and 6 illustrate top-down views of an inclined pin heatsink, according to an embodiment of the present invention.

FIG. 7 illustrates a schematic diagram of an exemplary prior art device.

FIG. 8 illustrates a perspective view of a heatsink device according to the prior art and parameters used for testing that prior art heatsink design.

FIG. 9 illustrates a schematic view of a computational model setup for testing the inclined pin heatsink of the present invention as well as testing prior art designs, as a point of comparison.

FIG. 10 illustrates the temperature profile of the system using the prior art heatsink design of FIGS. 3 and 4.

FIG. 11 illustrates the temperature profile for the inclined pin heatsink, according to an embodiment of the present invention.

FIG. 12 illustrates a graphical view of experimental performance of the inclined pin heatsink, according to an embodiment of the present invention.

FIG. 13 illustrates a graphical view of the performance of various heatsink designs and temperature reduction comparisons.

FIG. 14 illustrates a graphical view comparing the improvement in the lifespan of these electronic components.

### DETAILED DESCRIPTION OF THE PREFERRED EMBODIMENTS

The presently disclosed subject matter now will be described more fully hereinafter with reference to the accompanying Drawings, in which some, but not all embodiments of the inventions are shown. Like numbers refer to like elements throughout. The presently disclosed subject matter may be embodied in many different forms and should not be construed as limited to the embodiments set forth herein; rather, these embodiments are provided so that this disclosure will satisfy applicable legal requirements. Indeed, many modifications and other embodiments of the presently disclosed subject matter set forth herein will come to mind to one skilled in the art to which the presently disclosed subject matter pertains having the benefit of the teachings presented in the foregoing descriptions and the associated Drawings. Therefore, it is to be understood that the presently disclosed subject matter is not to be limited to the specific embodiments disclosed and that modifications and other embodiments are intended to be included within the scope of the appended claims.

An inclined pin heatsink is designed to provide efficient cooling in a small footprint. The inclined pin heatsink provides cooling directly, for example, to hot components of an electronic device, and more specifically provides cooling to hot components on a printed electronic circuit board (PCB). The inclined pin heatsink of the present invention achieves cooling without the need to bring heat out of a system with much bulkier and sizeable solutions.

In order to achieve improved cooling in a small footprint, a system of the present invention utilizes piezoelectrically controlled synthetic jets or microblowers and a vehicle for convective heat transfer, such as a heatsink, or more particularly, the inclined pin heatsink. The microblowers work in conjunction with the inclined pin heatsink, according to an embodiment of the present invention, to provide impingement cooling to the sources of heat in the electronic device. The microblowers are extremely small in size, very low power, and quiet. The present invention, therefore, provides a cooling method that brings cooling directly to hot components on a printed circuit board (PCB) or other location instead of bringing the heat out of the device with a much bulkier solution.

Further, the inclined pin heatsink of the present invention leverages geometries that are only made possible with the use of metallic additive manufacturing or 3D printing techniques. The uniqueness of the pin configuration of the present invention could not be manufactured by traditional fabrication techniques. After years of modeling, and iterative design concepts, to arrive at the design, the novel heatsink of the present invention is an improvement over the state of the art by more than several percentage points. The design and the performance advantages of the heatsink of the present invention will be described further, herein. Therefore, when used in an electronic device, the heatsink of the present invention offers components within an electronic device a lifetime increase by 30% or more.

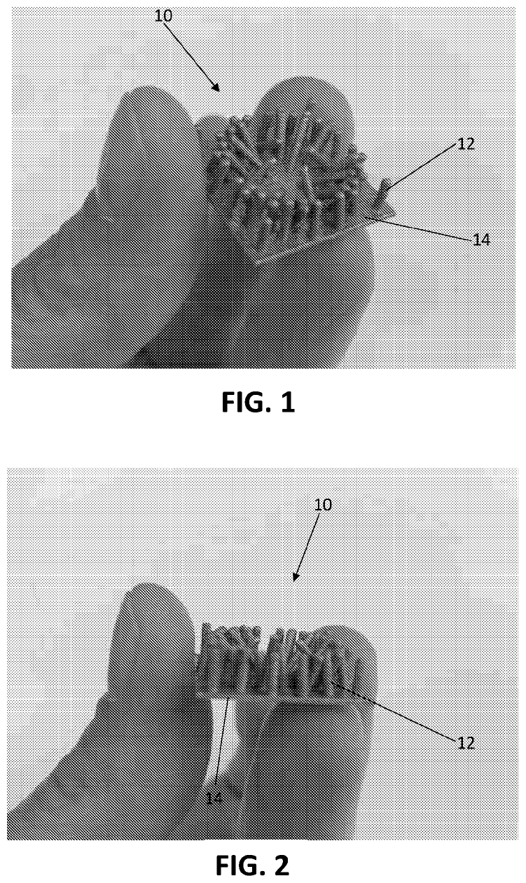

FIGS. 1 and 2 illustrate a perspective view and a side view, respectively, of an inclined pin heatsink, according to an embodiment of the present invention. The inclined pin heatsink 10 shown in FIGS. 1 and 2 was specifically designed for use with impingement cooling. The pins 12 are inclined to be more normal to the flow of fluid moving through the heatsink, and the pins 12 increase the surface area of the heatsink 10 within the fluid path without changing a height of the heatsink 10. This novel inclined pin design offers a significant improvement over the state of the art designs, as will be shown herein. As illustrated in FIGS. 1 and 2, a number of the pins 12 of the inclined pin heatsink 10 are angled either towards the center of the heatsink 10 or away from the center of the heatsink 10. Other pins remain perpendicular to the base 14. The number of pins 12 that are angled or perpendicular to the base can vary based on the size of the heatsink needed for the desired application. The inclined pin heatsink of the present invention can be formed from a metal, alloy, or other suitable material known to or conceivable by one of skill in the art. The inclined pin heatsink of the present invention is made via additive manufacturing or 3D printing, or any other suitable method of manufacturing known to or conceivable to one of skill in the art and that allows for the formation of the unique geometry of the inclined pin heatsink of the present invention.

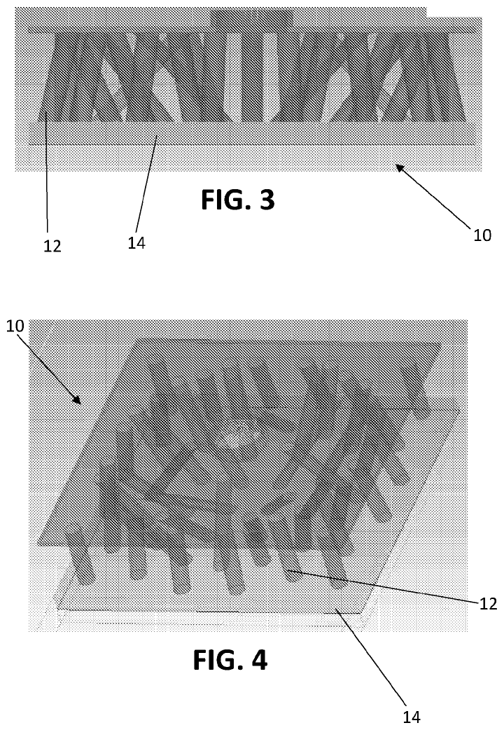

FIGS. 3 and 4 illustrate a side view and perspective view, respectively, of an inclined pin heatsink, according to an embodiment of the present invention. FIGS. 3 and 4 illustrate the arrangement of the pins 12 on the base 14 of the inclined pin heatsink, according to an embodiment of the present invention. The pins 12 can have a height defined by the size of the heatsink needed for the desired application or any other suitable method for determining the height of the pins known to or conceivable to one of skill in the art. The specific angles of each of the inclined pins can also be determined based on the height of the pins, size of the heatsink needed for the desired application, or any other criteria known to or conceivable to one of skill in the art.

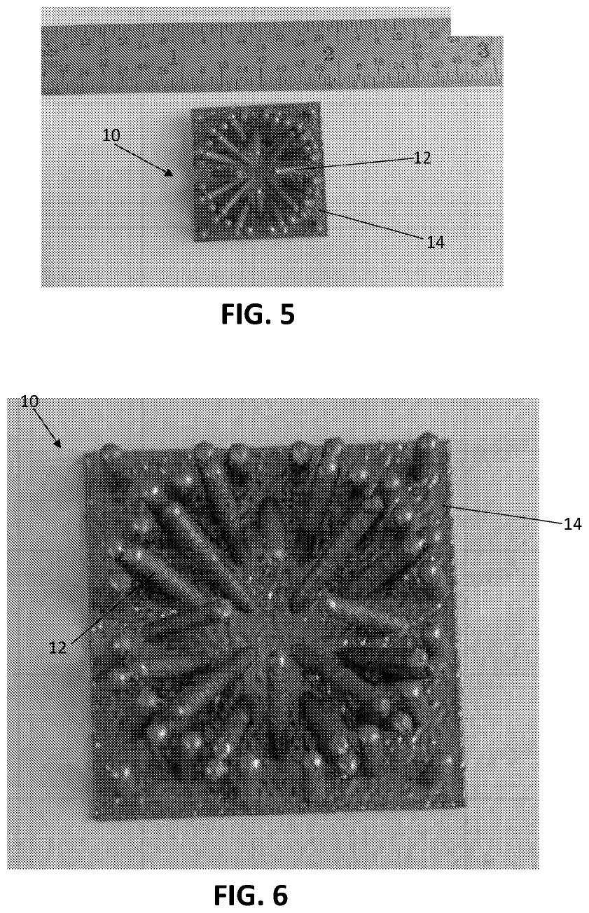

FIGS. 5 and 6 illustrate top-down views of an inclined pin heatsink, according to an embodiment of the present invention. FIGS. 5 and 6 further illustrate the arrangement of the pins 12 on the base 14 of the inclined pin heatsink, according to an embodiment of the present invention.

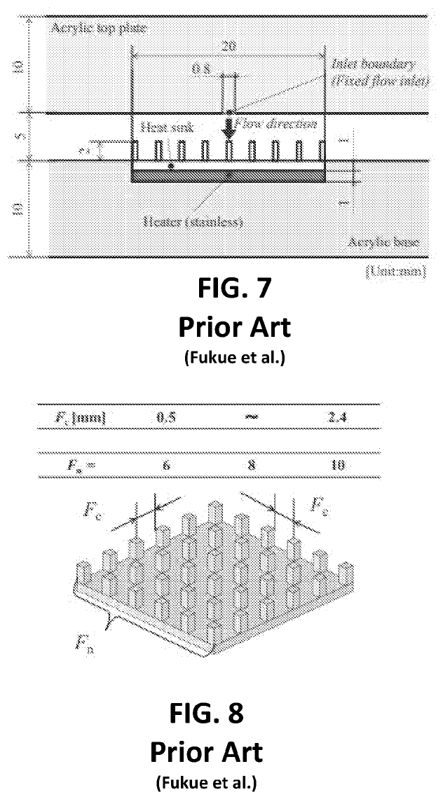

FIG. 7 illustrates a schematic diagram of an exemplary prior art device. FIG. 7 details a test set up for testing various heatsink designs utilizing microblower impingement cooling. FIG. 8 illustrates a perspective view of a heatsink device according to the prior art and parameters used for testing that prior art heatsink design. The prior art also defines exemplary heatsink test parameters, as shown in FIG. 8. The heatsink design shown in FIG. 8 was the prior art design with the best performance, according to the prior art studies. This prior art heatsink design was used as a basis of comparison for heatsink design of the present invention.

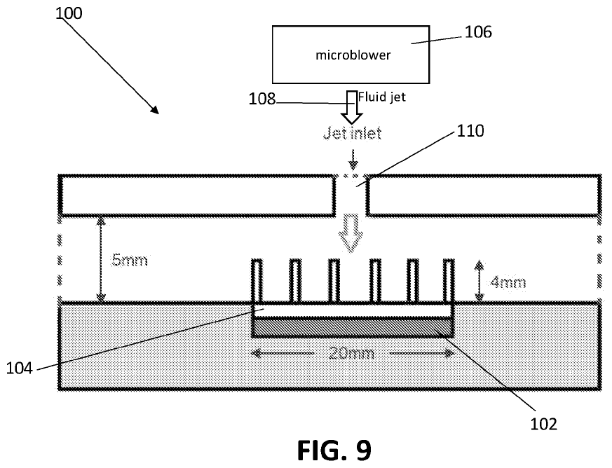

FIG. 9 illustrates a schematic view of a computational model system setup for the system and heatsink of the present invention as well as testing prior art designs, as a point of comparison. Here, the model system is being used to test the spiral fin heatsink of the present invention. The model system 100 used herein is set up very similarly to the prior art models. The hot component 102 is shown in dark grey, with the heatsink 104 sitting on top of the hot component 102. The microblower or synthetic jet 106 is positioned above the heatsink with the jet exhaust or fluid jet 108 pointing down toward the heatsink surface such that the jet exhaust travels through jet inlet 110 towards the heatsink 104.

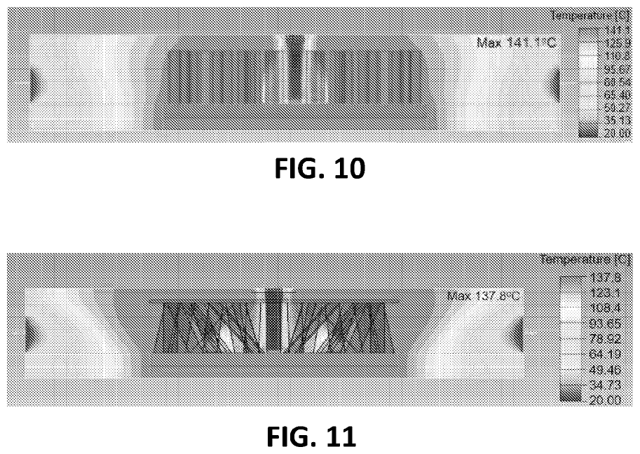

The schematic of FIG. 9 is also helpful with the visualization of the following thermal images. FIG. 10 shows the temperature profile of the system using the prior art heatsink design of FIGS. 3 and 4. The dark grey show the highest temperatures, 141 °C in this case, and move through the gradient, showing the coolest colors in light grey. This image is a slice of the temperature profile taken at the center. Just like the schematic shown in FIG. 9, the hot component is on the bottom, and the heatsink is installed on top of that. The jet comes from the top and strikes down onto the heatsink surface. The sides of the system are open.

FIG. 11 illustrates the temperature profile for the inclined pin heatsink, according to an embodiment of the present invention. For comparison, the same plot was taken for the model utilizing the inclined pin heatsink of the present invention. Better spreading of the cooler colors in the center of the heatsink can be seen, along with a lower overall temperature, as illustrated in FIG. 11. The temperature profile of FIG. 11 is also a center cut plane of the inclined pin heatsink.

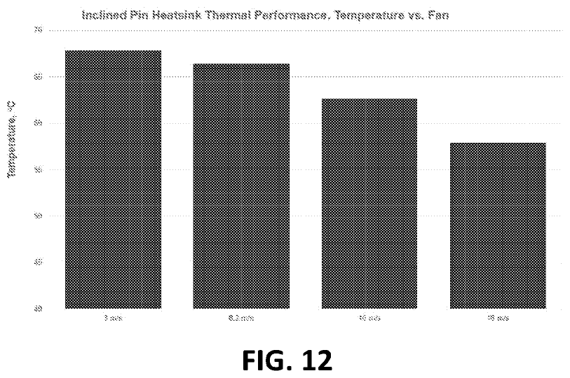

The use of the inclined pin heatsink of the present invention combined with the microblower provide a very compact, lightweight, low power cooling solution to packaged electronics and other devices that require cooling in a small footprint. In addition to the thermal considerations, the cooling solution of the present invention has a big thermal impact, while impacting the electrical system power as little as possible. In other words, by adding these cooling devices, the system power input is not burdened, nor is the operating time of the overall system depleted. The design of the present invention resolves a very widespread challenge of cooling electronic components in a totally unique way. FIG. 12 illustrates a graphical view of experimental performance of the inclined pin heatsink, according to an embodiment of the present invention. The resulting experimental performance of the heatsink tested for various microblower speeds can be seen in FIG. 12 below. At 16 m/s, the inclined pin heatsink of the present invention, the best performing pinned heatsink, reduced the heater temperature by more than 42 degrees.

This heatsink could be used for cooling any sort of electronics for commercial, industrial, residential, and government purposes alike. It would be of particular interest in space constrained applications such as vehicle mounted, UAV/drone, human-portable, or shipboard. On the commercial side, cell phone companies, computer companies and communications applications, especially for portable consumer electronics.

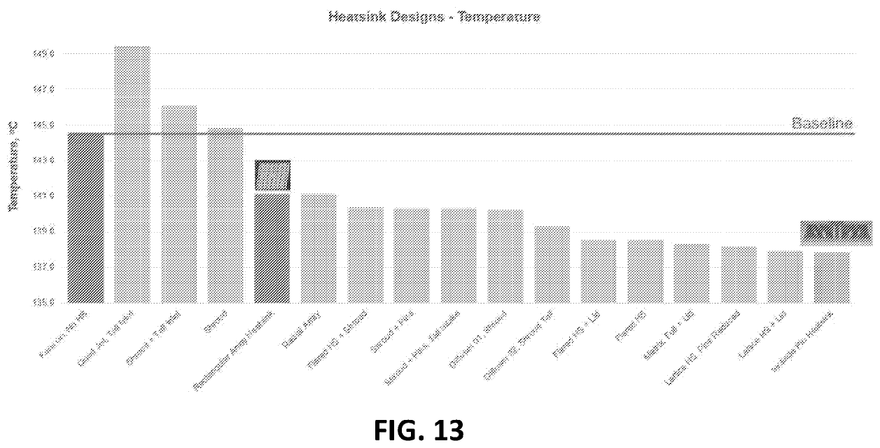

FIG. 13 illustrates a graphical view of the performance of various heatsink designs and temperature reduction comparisons. FIG. 13 shows a handful of the design concepts and highlights the advancement of the design of the present invention. In dark grey on the far left is the baseline data point, which is the system run with no heatsink on the heat source. The next dark grey bar is the current state of the art, and the medium grey bar represents the maximum temperature of the heat source utilizing the Inclined Pin Heatsink.

The design of the present invention stands out on its own. It has been designed, redesigned, tweaked, modeled, manufactured, and tested for a very specific and unique use case, but also could be used in any electronics design. It is small in scale, and it uses a geometry that is entirely original to provide the cooling. It combines the cooling effects of natural convection, conduction and impingement cooling with piezoelectric synthetic jets. The pinned design was specifically tailored to be manufactured with metallic additive manufacturing processes or 3D printing. The geometry could not be reproduced using traditional fabrication techniques. In contrast, present technology typically uses extruded or machined heatsinks (not 3D printed) for use in natural convection/conduction cooling applications or convective/forced cooling applications. Heatsinks using impingement cooling are not typical nor is the use of a synthetic jet as the impingement medium.

In electronic designs, there is an industry rule of thumb where for every drop of 10 °C in temperature, it can double an electronic component's lifespan. This is not a hard and fast rule, but the Arrhenius equation relates the rate of chemical reactions, to temperature, to failure mechanisms that occur in electronics. This assumes a certain activation energy, and there are obviously other failure modes that electronics can see, but this is an industry goal in packaging designs.

In the models described herein, the prior art heatsink described with respect to FIGS. 7 and 8 reduced the temperature of the component by 3.4 °C when compared to a design that did not use a heatsink. This is a 34% increase in the lifetime of the component.

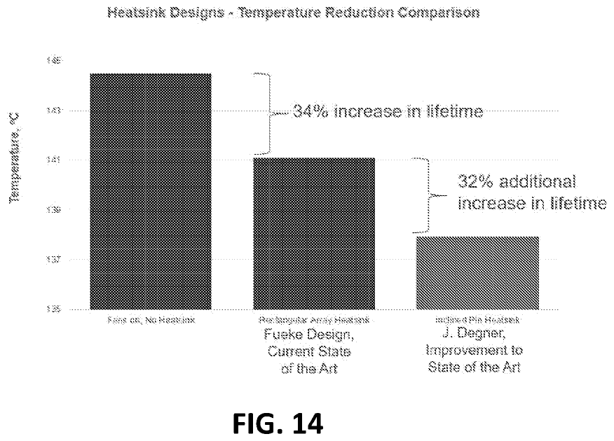

The inclined pin heatsink, according to an embodiment of the present invention, further reduced the temperature, increasing the lifetime of the component by an additional 32%, for a total of a 66% increase in component lifetime when compared to not using a heatsink. FIG. 14 illustrates a graphical view comparing the improvement in the lifespan of these electronic components.

While the design of the present invention can be generated on virtually any scale, the design is particularly well suited for micro scale applications. The heatsinks of the present invention are about 1″ square and less than 0.167″ tall. Existing heatsinks are many orders of magnitude larger, for example, with a 3″ base, and the fins having a length of 1.875″. In addition, existing heatsinks use a conventional fan with a larger height while the design of the present invention is utilizing a synthetic jet with a height less than ⅛ of an inch.

The fabrication processes for the heatsinks of the present invention versus those for existing heatsinks differ greatly. A central design difference is the central cylindrical core of the heatsink. The design of existing heatsinks fill in that space with a conductive material and uses that as the base or a core for all the heatsink fin designs. The design of the present invention actually does the opposite. The designs of the present invention keep that central space open and use it as a passage for impinging airflow. While the existing heatsinks close in the space that is blocked by the hub of a fan and use the fan blade locations to blow air over the heatsink fins, the design of the present invention uses a jet that blows down through the central location and then forces air through the fins.

Both the machining process and the secondary assembly steps to mount the fins of existing heatsinks vary dramatically compared to the designs of the present invention. The heatsinks of the present invention are fabricated using metallic additive manufacturing processes, such as 3D printing. Although the two designs could be made using similar materials in the heatsinks, the heatsinks of the present invention can be mass produced with no secondary assembly or bonding necessary. The existing heatsinks need to be individually machined, and likely have a secondary hand-touch assembly step, making them much more expensive in terms of labor.

Larger scale assembly of the devices differ as well. The existing heatsink design includes a heatsink held in place with a shroud, and a fan mounted to the shroud. The design of the present invention is shroudless. The heatsink of the present invention is mounted directly onto the heat source, and the synthetic jet rests on top of the heatsink, secured in place with screws to the printed circuit board. There is no shroud or additional assembly steps required.

Another major difference between existing heatsink designs and the present invention are the methods of cooling. Although they both use forced air cooling, the existing design adds a solid mass of conductive material (Al, Cu, etc.) to the central core and fins radially stem from that central core. The forced air from the fan, moving across the fins adds convective cooling to the assembly. In the design of the present invention, impingement cooling is used, where a high velocity jet strikes a targeted surface, in this case the heatsink base, and transfers heat from the surface to the fluid (air), then the flow moving from the strike surface is directed through optimized fins for both conductive and convective cooling.

In addition, the design of the present invention differs greatly because of the use of a synthetic jet versus a traditional fan. Synthetic jets have no bearings, so they are not susceptible to mechanical wear on those parts. They also have no fan blades. Because of these differences, synthetic jets tend to have a longer life and are quieter than traditional fans. In addition, synthetic jets tend to be lower power than traditional fans. Synthetic jets also functional differently than fans, and they can be used within contained environments (think inside an electronic enclosure), where fans need an inlet and exhaust point in the designs and enclosures.

The design of the present invention is also not constrained by the size of the fan hub or cylindrical core of the heatsink. The design of the present invention can be scaled up or down and tailored to match the size of the individual component or heat source. In addition, because of the small size of the heatsink of the present invention, multiple can be used in a single enclosure, designed on an individual chip basis on a multi-chip board, and they can be spaced much more closely than the existing design. They are also a fraction of the weight of the existing design.

The heatsinks of the present invention are all unique designs that are made in one fabrication step and do no rely on precision assembly. The heatsinks of the present invention can be made in quantity with no additional assembly needed.

Although the present invention has been described in connection with preferred embodiments thereof, it will be appreciated by those skilled in the art that additions, deletions, modifications, and substitutions not specifically described may be made without departing from the spirit and scope of the invention as defined in the appended claims.

1. A device for impingement cooling comprising:
a base;
pins extending from the base, wherein a number of the pins are arranged at a number of angles to the base.

2. The device of claim 1, wherein the angles to the base are greater than 90°.

3. The device of claim 1, wherein the angles to the base are less than 90°.

4. The device of claim 1, wherein the angles to the base include angles that are greater than 90°, less than 90°, and equal to 90°.

5. The device of claim 1, wherein some of the number of the pins are angled toward a center of the device.

6. The device of claim 1 wherein some of the number of pins are angled away from a center of the device.

7. The device of claim 1 wherein some of the number of the pins are angled toward a center of the device and others of the number of pins are angled away from a center of the device.

8. The device of claim 1 formed from one selected from a group consisting of a metal, an alloy, or a conductive material.

9. The device of claim 1 wherein the device is formed by additive manufacturing.

10. The device of claim 1 wherein the device is formed by three-dimensional printing.

11. A system for impingement cooling comprising:
a microblower;
a heatsink comprising:
a base;
pins extending from the base, wherein a number of the pins are arranged at a number of angles to the base.

12. The system of claim 11 wherein the microblower comprises piezoelectrically controlled synthetic jet.

13. The system of claim 11, wherein the angles to the base are greater than 90°.

14. The system of claim 11, wherein the angles to the base are less than 90°.

15. The heatsink device of claim 1, wherein the angles to the base include angles that are greater than 90°, less than 90°, and equal to 90°.

16. The system of claim 11, wherein some of the number of the pins are angled toward a center of the device.

17. The system of claim 11 wherein some of the number of pins are angled away from a center of the device.

18. The system of claim 11 wherein some of the number of the pins are angled toward a center of the heatsink device and others of the number of pins are angled away from a center of the device.

19. The system of claim 11 formed from one selected from a group consisting of a metal, an alloy, or a conductive material.

20. The system of claim 11 wherein the device is formed by additive manufacturing.

21. A system for impingement cooling comprising:
a piezoelectrically controlled synthetic jet;
a heatsink comprising:
base;
a fluid flow path defining structure disposed on the base.
